(19) United States
(12) Patent Application Publication
(10) Pub. No.: US 2006/0112877 A1
(43) Pub. Date: Jun. 1, 2006

(54) Nozzle and plasma apparatus incorporating the nozzle

(76) Inventors: Ahn-Sik Moon, Suwon-si (KR); Joo-Pyo Hong, Seoul (KR)

Correspondence Address: HARNESS, DICKEY & PIERCE, P.L.C., P.O. BOX 8910, RESTON, VA, 20195, US

(21) Appl. No.: 11/331,227

(22) Filed: Jan. 13, 2006

Related U.S. Application Data
(63) Continuation-in-part of application No. 10/918,490, filed on Aug. 16, 2004.

(30) Foreign Application Priority Data
Jan. 14, 2005 (KR) 2005-03846
Nov. 3, 2003 (KR) 2003-77396
Apr. 12, 2004 (KR) 2004-25097

(51) Int. Cl. C23C 16/00; H01L 21/306; B67D 5/37

(52) U.S. Cl. 118/715; 156/345.33; 137/801

(57) ABSTRACT

Provided are improved nozzles suitable for injecting source gases or other gases into a plasma chamber in which the gas is conveyed along a single passage or channel to an outlet region at which point the single channel is divided into a plurality of outlet channels. The outlet channels are configured to suppress formation of a plasma within the nozzle itself, thereby reducing deposition and/or damage within the nozzle. The outlet channels may be defined through the use of one or more insertion members that can be inserted in the outlet region of the nozzle and may be used in combination with an outer pipe attached to a supply pipe for completing the nozzle assembly.

### PRIORITY STATEMENT

This application is a Continuation-In-Part application of U.S. application Ser. No. 10/918,490, filed on Aug. 16, 2004, which claimed priority on Korean Patent Application No. 2003-77396 filed Nov. 3, 2003, and Korean Patent Application No. 2004-25097, filed Apr. 12, 2004; and which claims priority of Korean Patent Application No. 2005-03846, filed on Jan. 14, 2005, in the Korean Intellectual Property Office, the disclosures of all of which are incorporated herein, in their entirety, by reference.

### BACKGROUND OF THE INVENTION

1. Field of the Invention

The present invention relates to an apparatus for manufacturing semiconductor devices and, more particularly, to a nozzle configured for injecting one or more source gases into a semiconductor manufacturing apparatus and plasma equipment incorporating one or more such nozzles.

2. Description of Related Art

A process widely utilized during the fabrication of most modern semiconductor devices is chemical vapor deposition for forming a variety of thin films on a semiconductor substrate by chemically reacting one or more source gases. In recent years, high density plasma chemical vapor deposition (“HDP-CVD”) apparatus have become more widely used in CVD processes for depositing material in high-aspect-ratio openings or structures. A typical HDP-CVD apparatus includes a process chamber in which high-density plasma ions are produced from one or more source gases in order to deposit a layer on a semiconductor wafer while simultaneously etching the substrate with an inert gas and thereby fill high-aspect-ratio gaps while reducing the occurrence of voids.

A conventional HDP-CVD apparatus will typically plurality of nozzles or a “showerhead” positioned within the deposition or reaction chamber for injecting mixed source gases into the chamber. A radio frequency (R-F) coil is provided adjacent an outer surface of the chamber for selectively applying high-frequency power to the source gas(es) within the chamber for exciting the source gas(es) to form a plasma within the chamber. During deposition processes, a portion of the reaction products and/or byproducts will be deposited on the inner wall surfaces of the chamber. Portions of these surface deposits may subsequently become detached from the surfaces and become particle contamination if deposited on substrates within the chamber and/or carried to subsequent processes. Accordingly, after processing a designated number of wafers, or according to some other periodic schedule, the inside surfaces of the chamber are typically cleaned using an etch gas to reduce or eliminate product and/or byproduct deposits as a potential source of particulate contamination.

A conventional nozzle used in an HDP-CVD apparatus has a through-hole formed at its center that serves as a path for the source gas(es). However, in some instances, the source gases may be sufficiently excited by the applied high-frequency power to form a plasma while still in the nozzle, react with one another, and deposit material on the nozzle. In particular, the material formed by the premature plasma will tend to deposit near the lip of the nozzle and the inner surfaces near the lip with the thickness of the deposits tending to increase over time.

Because the deposited material can serve as a particulate source during subsequent processing, the upper inside surfaces of the nozzles are also typically cleaned at the same time the inner wall of the chamber are being cleaned. However, the thickness of the material deposited on the nozzle surfaces tends to be thicker, sometimes on the order of three or four times thicker, than the material deposited on the inner walls of the chamber over the same period. Accordingly, the duration of the etch necessary to remove the deposits from the nozzles reduces the equipment operating rate or up time with corresponding decreases in the throughput and processing yield. Moreover, the extent of the overetch to which the inner wall and other surfaces of the chamber are subjected while cleaning the nozzles will tend to shorten the operating life of various components of the apparatus.

### SUMMARY OF THE INVENTION

Example embodiments of the present invention include a range of nozzles configured for supplying source gases into a plasma treating apparatus that include a single channel section connected to a gas supply assembly and a multiple channel section extending from the single channel section. A single gas path, also referred to as a pathway, conduit or passage, is formed in the single channel section and a plurality of gas paths, each having a cross-sectional area smaller than that of the single gas path, are formed in the multiple channel section. The various paths included in the multiple channel section can be arranged regularly around the central axis of the multiple channel section with each of the peripheral paths being generally wedge shaped or fan shape shaped.

In some embodiments of the present invention, the multiple channel section may include an outer pipe that extends from the single channel section and an insertion member inserted into the outer pipe for dividing the interior of the outer pipe into a plurality of paths. The insertion member may have a plurality of plates having a first edge disposed at or adjacent the center of the outer pipe and an opposing edge that is in contact with or adjacent to the inner sidewall of the outer pipe. In most instances, the plates may number from about 3 to 8 and can be arranged in a variety of configurations, including a generally radial configuration at regular angular intervals about the central axis of the nozzle. The various paths of the multiple channel section may further include a central path disposed at the center of the multiple channel section. Preferably, the multiple channel section has a length of at least 4 millimeters.

Example embodiments of the present invention provide a nozzle configured for supplying source gases to the process chamber of an apparatus, a supply pipe connected to an external gas supply assembly for supplying source gases into the process chamber and an outer pipe having an inlet portion surrounding an outer sidewall of the supply pipe and an outlet portion extending upwardly from the bottom part. An insertion member is disposed in the outlet portion of the outer pipe for dividing the outlet portion into a plurality of smaller gas paths.

In some example embodiments of the present invention, the insertion member may include a plurality of plates oriented with one edge disposed toward the center of the outer pipe and an opposing edge disposed in contact with or adjacent to an inner sidewall of the outer pipe. The insertion member may be merged into the outer pipe and may be superposed on the supply pipe. The plates forming the insertion member may number from 3 to 8 and are typically arranged at regular angular intervals. The gas paths formed at the multiple channel section may further include a central path formed at the center of the multiple channel section. The length of the multiple channel section will be sufficient to suppress (where “suppress” may mean eliminate or reduce) plasma formation within the nozzle, typically at least 4 millimeters.

Example embodiments of the present invention include nozzles that may be used in a plasma treating apparatus that include a single channel section in which a gas path is formed and a multiple channel section through which a plurality of gas paths having reduced dimensions are arranged in a lattice format. The single channel section is connected to a gas supply assembly and conveys the source gases to the multiple channel section. The multiple channel section includes an outer pipe extending from the single channel section and an insertion member positioned within the outer pipe to divide the outer pipe into a plurality of paths. The insertion member has first members arranged in a first direction and second members arranged in a second direction and generally perpendicular to the first members to form a “lattice” configuration in the multiple channel section having a length of at least 4 millimeters.

Example embodiments of the present invention provide nozzles used in a substrate treating apparatus and include a single channel section through which a single gas path is formed and a multiple channel section through which a plurality of paths are arranged in a lattice format. The single channel section is connected to a gas supply assembly. Each of the respective paths in the multiple channel section is smaller than the path in the single channel section. The multiple channel section includes an outer pipe extending from the single channel section, an inner pipe inserted into the outer pipe, and an insertion member for dividing the inside of the inner pipe into a plurality of generally wedge-shaped fan-shaped paths. The nozzle may also include at least one insertion pipe arranged between the inner pipe and the outer pipe. The nozzle may further include one or more plates inserted between the inner pipe and the outer pipe for dividing the annular space formed therebetween into a plurality of paths with one edge of the plate is in contact with another sidewall of the inner pipe, and the opposed edge of the plate in contact with or adjacent an inner sidewall of the outer pipe. The multiple channel section will typically have a length of at least 4 millimeters.

Example embodiments of the present invention provide nozzles that may be used in a substrate treating apparatus and include a single channel section through which a single path is formed and a multiple channel section through which a plurality of paths are formed. The sizing of the respective paths through the multiple channel section is smaller than the path through the single channel section. The multiple channel section includes an outer pipe extending from the single channel section, an inner pipe inserted into the outer pipe, and at least one plate inserted between the outer pipe and the inner pipe to form a plurality of paths therebetween. One edge of the plate will be in contact with or closely adjacent an outer sidewall of the inner pipe and the opposing edge of the plate will be in contact with, or closely adjacent, an inner sidewall of the outer pipe. The multiple channel section will typically have a length of at least 4 millimeters.

Example embodiments of the present invention provide an apparatus for treating substrates using plasma and including a process chamber encompassing a substrate supporter on which a substrate is placed, a nozzle according to one of the embodiments described above configured for injecting one or more source gases into the process chamber, and an energy source for supplying energy sufficient to excite the injected source gases into plasma.

### BRIEF DESCRIPTION OF THE DRAWINGS

FIG. 1 is a cross-sectional view of a high density plasma chemical vapor deposition apparatus (HDP-CVD apparatus) according to an example embodiment of the present invention.

FIG. 2 is a schematic view of a gas supply assembly for supplying source gases to a nozzle shown in FIG. 1.

FIG. 3 is a perspective view of a nozzle according to an example embodiment of the present invention.

FIG. 4 is a top plan view of FIG. 3.

FIG. 5 is a cross-sectional view taken along a line A-A of FIG. 4.

FIG. 6 is a perspective view of an insertion member shown in FIG. 3.

FIG. 7 is a top plan view, which shows a modified example of the nozzle shown in FIG. 3.

FIG. 8 is a perspective view of a nozzle, which shows a modified example of the insertion member shown in FIG. 3.

FIG. 9 is a top plan view of FIG. 8.

FIG. 10 is a cross-sectional view taken along a line B-B of FIG. 9.

FIG. 11 and FIG. 12 show the relative regions in which source gas(es) may be sufficiently excited to form a plasma using a conventional nozzle and a nozzle according to the present invention, respectively.

FIG. 13 is an exploded perspective view of another example of the nozzle shown in FIG. 3.

FIG. 14 is a coupling cross-section view of the nozzle shown in FIG. 13.

FIG. 15 is a top plan view of another example of the nozzle shown in FIG. 3.

FIG. 16 is a cross-sectional view taken along a line C-C of FIG. 15.

FIGS. 17-19 are top plan views of other examples of the nozzle shown in FIG. 3, respectively.

These drawings have been provided to assist in the understanding of the example embodiments of the invention as described in more detail below and should not be construed as unduly limiting the invention. In particular, the relative spacing, positioning, sizing and dimensions of the various elements illustrated in the drawings are not drawn to scale and may have been exaggerated, reduced or otherwise modified for the purpose of improved clarity. Those of ordinary skill in the art will also appreciate that a range of alternative configurations have been omitted simply to improve the clarity and reduce the number of drawings. Similarly, those of ordinary skill will appreciate that certain of the various structural elements illustrated in the example embodiments may be selectively and independently combined to form other structural configurations with departing from the scope and spirit of this disclosure.

### DETAILED DESCRIPTION OF EXAMPLE EMBODIMENTS

The present invention will now be described more fully hereinafter with reference to the accompanying drawings, in which certain example embodiments of the invention are shown. The invention may, however, be embodied in different forms and should not be construed as limited to the example embodiments set forth herein. Rather, these example embodiments are provided so that this disclosure will be thorough and complete, and will fully convey the scope of the invention to those skilled in the art. Further, although the invention will be described in relation to a high density plasma chemical vapor deposition (HDP-CVD) apparatus, the present invention is not so limited and may be suitable for use in other plasma deposition apparatuses.

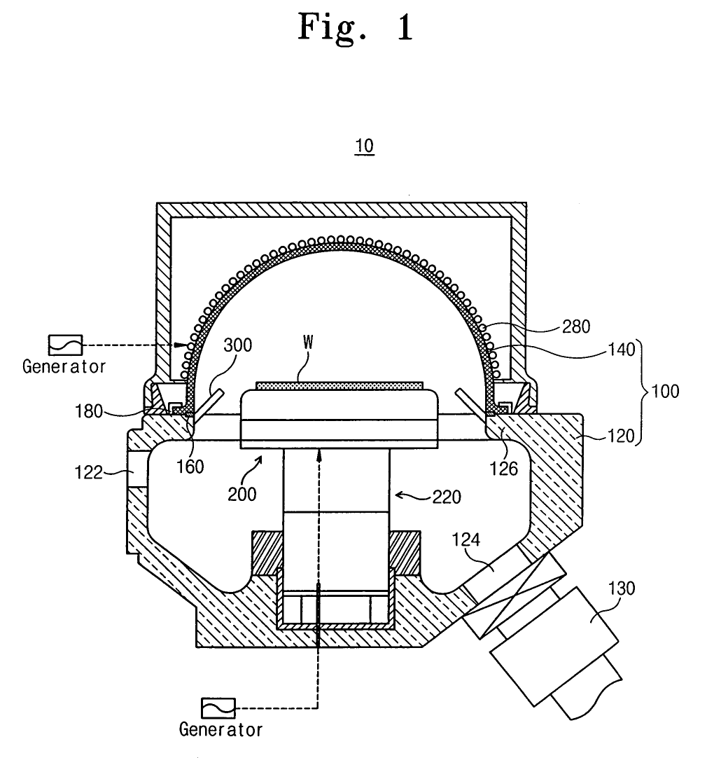

A cross-sectional view of an HDP-CVD apparatus 10 according to an example of the present invention is illustrated in FIG. 1. The apparatus 10 includes a process chamber 100, also referred to by other terms for example plasma chamber, reaction chamber, etch chamber and/or deposition chamber, a substrate supporter 200, a supporter driver assembly 220, a top electrode 280, a bottom electrode (not shown), and a nozzle 300. The process chamber 100 defines a space within which a subatmospheric deposition process is performed. The process chamber 100 includes both a lower chamber 120 and an upper chamber 140. The lower chamber 140 includes an open top, a sidewall where a wafer-return path 122 is provided, and a bottom sidewall where an exhaust port 124 is provided

As illustrated in FIG. 1, an exhaust pipe 130 is connected to the exhaust port 124 whereby reactive products or byproducts created during the deposition process are removed through the exhaust pipe 130. A vacuum pump (not shown) may be connected to the exhaust pipe 130 for maintaining the pressure within the sealed process chamber 100 within a pressure range (typically subatmospheric) during the deposition process.

An extension, lip or flange 126 protrudes inwardly from the top of the sidewall of the lower chamber 120. The upper chamber 140 is placed on the flange 126 and may be a dome-shaped quartz structure having an open bottom. An O-ring 160 or other sealing member may be provided between opposing surfaces of the upper and the lower chambers 140 and 120 to seal the inside of the process chamber 100. A cooling member 180 may be provided to limit deformation of the O-ring resulting from heat absorbed from the process chamber during the deposition and/or etch processes.

A top electrode 280 may be arranged over the exterior surface of the upper chamber 140 as coil and connected to a power source that may be capable of generating frequencies between about 100 kHz and 13.56 MHz and applying power levels between about 3,000 watts and 10,000 watts. The top electrode 280 serves as an energy source applying or radiating energy into the upper chamber 140 to excite the source gas(es) injected into the upper chamber 140 and forms a plasma.

A substrate chuck, stage or supporter 200 is provided in the lower chamber 120 for receiving and supporting a wafer W during the deposition and/or etch processes. The substrate supporter 200 may be an electrostatic chuck that holds the wafer W on the chuck by an electrostatic force. Although not illustrated, a lift pin assembly may be provided under the substrate supporter 200 for lifting the wafer W from the substrate supporter 200 in cooperation with one or more transfer robots (not shown) for transferring the wafer W within the lower chamber 120. A bottom electrode (not shown) is typically provided at the substrate supporter 200 for inducing the plasma created in the process chamber 100 to move toward the wafer W by establishing bias power at the bottom electrode. The applied bias power may fall within a frequency range between about 100 KHz and 13.56 MHz and have a power level between about 1,500 and 5,000 watts.

The supporter driver assembly 220 is arranged for moving the substrate supporter 200 up and down in the process chamber 100. When the wafer W is inserted into or removed from the process chamber 100, the substrate supporter 200 is positioned below an opening 122 formed through a sidewall of the lower chamber 120. Once the wafer W is in place, the supporter may be moved into the upper chamber 140 for the deposition and/or etch processes.

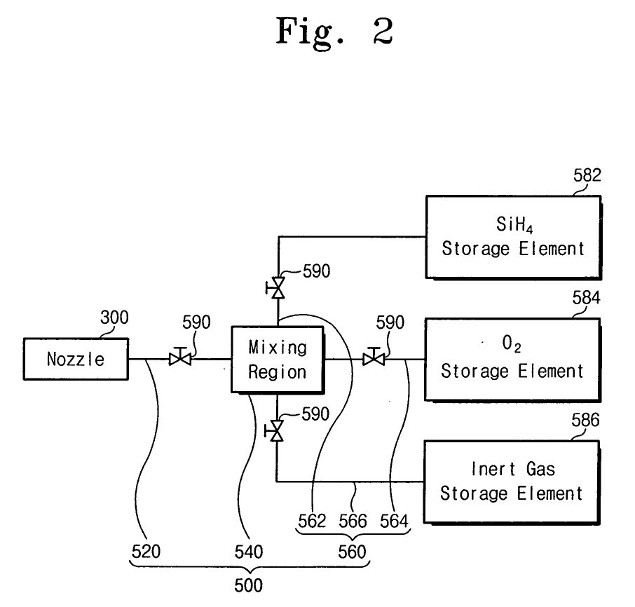

Source gases are supplied into the upper chamber 140 through a nozzle assembly 300 that includes a plurality of nozzles arranged around an upper portion of an inner sidewall of the lower chamber 120 and directed into the space in the upper chamber 140 above the wafer W. The nozzle assembly 300 receives gases from a gas supply assembly (500 of FIG. 2). The individual nozzles included in the nozzle assembly 300 may be arranged in regular intervals and may supply the same source gas mixture. The source gases supplied to the nozzle assembly 300 typically contain at least one gas mixture.

An example gas supply assembly 500 is schematically illustrated in FIG. 2. The gas supply assembly 500 includes a main line 520, a mixing region 540, a plurality of sub-lines 560, and gas storage elements 582, 584 and 586. Gases ready to be supplied to the nozzle assembly 300 are stored in the gas storage elements 582, 584 and 586, respectively and are supplied to the mixing region 540 through their respective sub-lines 560. When silicon oxide (SiO₂) is deposited on a wafer W, silane (SiH₄) may be supplied through a first sub-line 562 and oxygen (O₂) may be supplied through a second sub-line 564. In order to fill a contact hole having a high aspect ratio, an inert gas for example helium (He) or argon (Ar) may be supplied through a third sub-line 566 for inducing an etch process in combination with the deposition process. Although not illustrated, the gas mixture supplied to the nozzle assembly 300 may also include one or more carrier gases.

The gases are delivered to the mixing region 540 through their respective sub-lines 562, 564 and 566 and are mixed there before being transferred to the nozzle assembly 300 through the main line 520. A plurality of valves 590 for opening/closing the various lines and the sub-lines and a plurality of flow control valves (not shown) for controlling flow rates of the various gases and the gas mixture through their respective lines may be installed at the respective sub-lines 562, 564, and 566 and the main line 520.

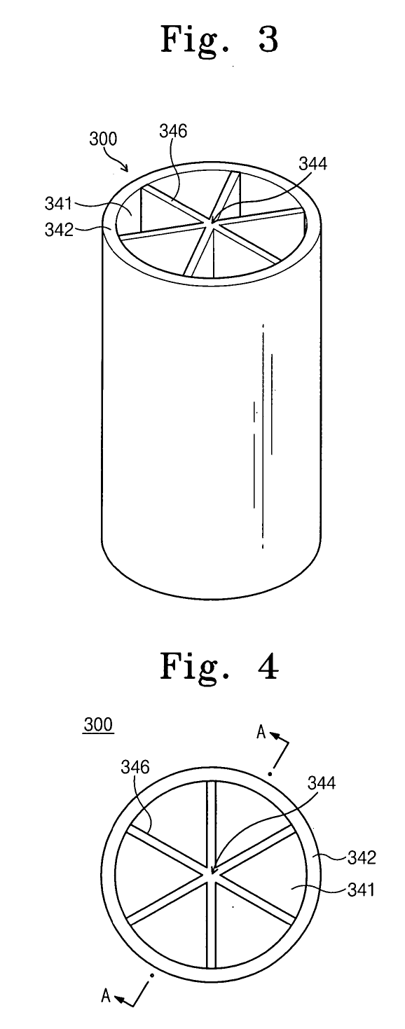

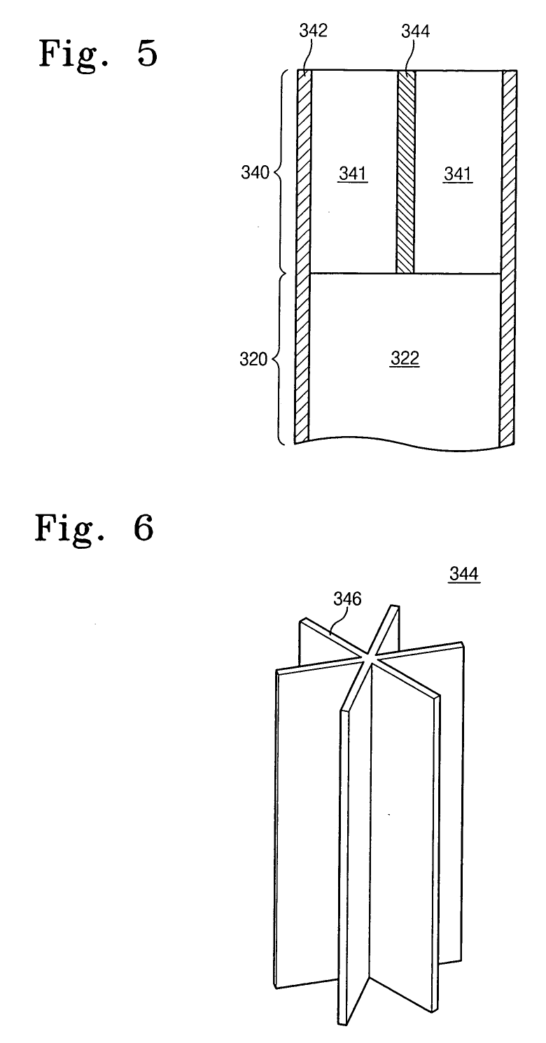

FIG. 3 is a perspective view of the nozzle assembly 300 according to an embodiment of the present invention. FIG. 4 is a top plan view of FIG. 3, and FIG. 5 is a cross-sectional view taken along a line A-A of FIG. 4. As illustrated in FIGS. 3-5, the nozzle assembly 300 includes a single channel section 320 through which a single path 322 is formed and a multiple channel section 340 through which a plurality of paths 341 are formed. The single channel section 320 is connected to a gas supply assembly 500, and the multiple channel section 340 extends in a downstream direction from the single channel section 320. The respective paths formed in the multiple channel section 340 are smaller in cross section than the path formed in the single channel section 320. Source gas streams initially flowing along the path 322 will be divided into a plurality of streams flowing along the paths 341 upon reaching the multiple channel section 340.

The multiple channel section 340 has an outer pipe 342 and an insertion member 344. The outer pipe 342 extends outwardly from the single channel section 320, typically deeper into the process chamber and away from the walls of the process chamber. The outer pipe 342 of the multiple channel section 340 and the single channel section 320 may be formed as a single pipe or as discrete structural elements. The insertion member 344 is inserted into the outer pipe 342 and divides the area within the outer pipe 342 into a plurality of paths 341.

As illustrated in FIGS. 3, 4 and 6, the plates or sheets that form the insertion member can be configured whereby the plates 346 can be commonly attached along or near a central axis with the individual plates extending outwardly from the center in a generally radial direction. As also illustrated in FIGS. 3, 4, and 6, the plates may be regularly or evenly spaced, in this instance about every 60°, to divide the multiple channel section into relatively uniformly shaped and distributed gas paths 341. Those skilled in the art will, however, appreciate that such spacing and uniformity is not required, so long as the sizing of the resulting gas paths is sufficient to suppress (where “suppress” may mean eliminate or reduce) the formation of a plasma within the perimeter of the nozzle itself.

FIG. 6 is a perspective view of the insertion member 344 shown in FIGS. 3-5. As illustrated in FIG. 6, the insertion member 344 has six plates 346 each having the same generally rectangular shape, with one edge of the plates 346 disposed centrally and adjacent plates 346 extending outwardly in a generally radial direction and disposed at an angular interval of about 60 degrees. As will be appreciated, adding plates will tend to reduce the angular spacing of the plates while, conversely, reducing the number of plates will tend to increase the angular spacing. According to the above configuration, when the insertion member 344 is inserted into the outer pipe 342, one edge of the respective plates 346 will be disposed near the center of the outer pipe 342 with the other edge being in contact with or adjacent to an inner sidewall of the outer pipe 342.

Due to the shape of the insertion member 344, the paths 341 formed in the multiple channel section 340 surround the center of the outer pipe 342. Each of the paths 341 is wedge or fan-shaped and may be referred to as a peripheral path. The insertion member 344 may be manufactured independently of the outer pipe 342 before being installed in the outer pipe 342. Alternatively, the insertion member 344 and the outer pipe 342 may be manufactured monolithically.

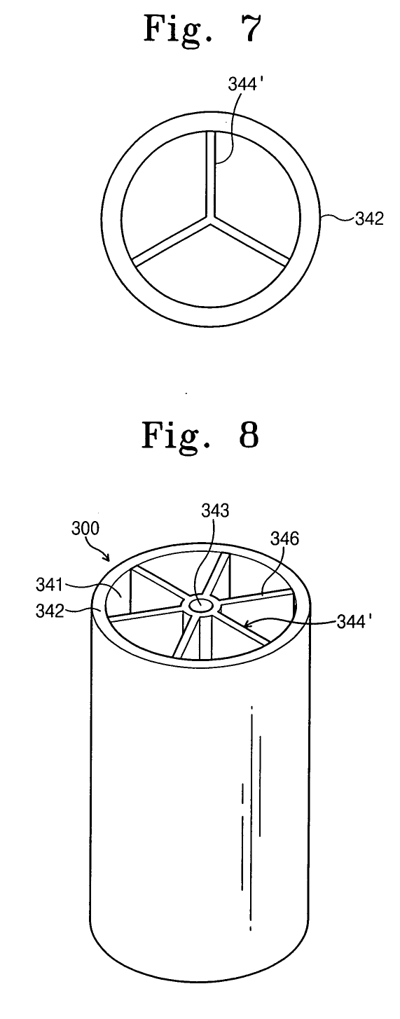

As noted above and illustrated in FIGS. 3-6, the insertion member 344 includes six plates 346, thereby forming six peripheral paths 341 in the multiple channel section 340. The number of plates 346, however, may vary with the path area of the outer pipe 342 and the anticipated operating conditions, as illustrated in FIG. 7. That is, more plates 346 may be utilized if the outer pipe 342 has a large path area, while fewer plates 346 may be utilized if the outer pipe 342 has a small path area. Because a smaller number of plates 346 lead to wider paths in the multiple channel section 340, the risk that the source gases may be excited into plasma increases. Because a larger number of plates 346 lead to increasingly complex configurations of the nozzle assembly 300, it is anticipated that about 3-8 plates 346 will generally be suitable for most applications.

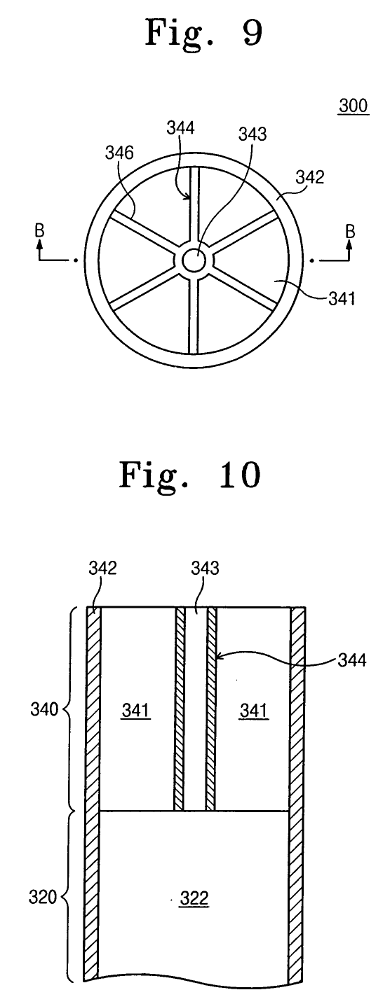

FIG. 8 is a perspective view of a nozzle assembly 300, which shows a modified example of the insertion member shown in FIG. 3. FIG. 9 is a top plan view of FIG. 8. As illustrated in FIGS. 8 and 9, an insertion member 344′ has a plurality of plates 346 arranged at regular angles (see FIG. 6). An additional path 343 is provided at the center of the insertion member 344′. Thus, when an insertion member corresponding to 344′ is used, the multiple channel section 340 will have both a plurality of peripheral paths 341 and a central path 343. Due to the central path 343, the areas of the peripheral paths in the multiple channel section 340 are reduced without increasing the number of the plates 346 used in the insertion member 344′. In order to prevent excitation of a source gas in the central path 343 into plasma, the central path is relatively small, typically having a diameter of no more than about 2 millimeters.

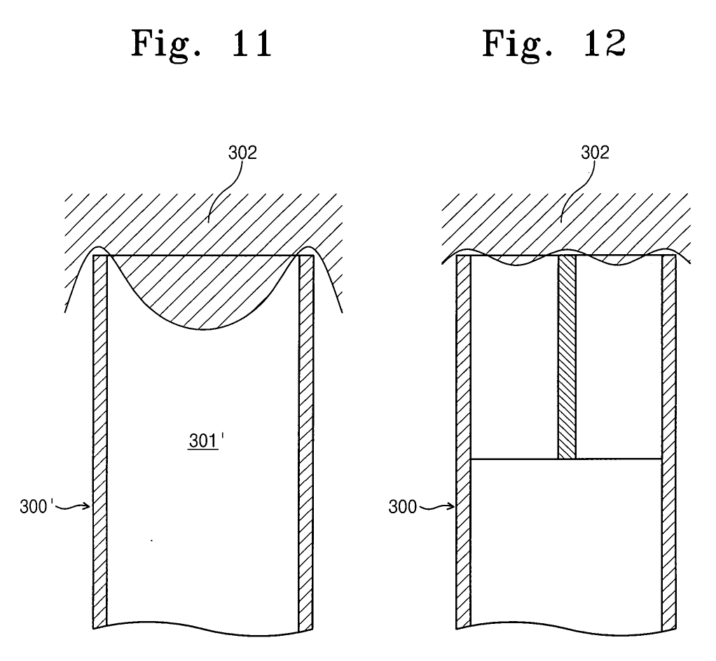

FIGS. 11 and 12 illustrate the respective regions in which a source gas is sufficiently excited to form a plasma 302 in both a conventional nozzle 300′ and a nozzle 300 according to the present invention, respectively. In FIGS. 11 and 12, the conventional nozzle 300′ includes a path 301′ haves a relatively large area, while the inventive nozzle 300 having a similar external diameter includes a plurality of paths 341 each having a relatively small area. When sufficient high-frequency energy is applied to a top electrode and a bottom electrode, the source gas or gases will be excited and form a plasma in the process chamber 100 as well as terminal portions of nozzles supplying the source gas.

At the terminal portions of a nozzle, the region of plasma formation will increase as the areas of source gas paths increase. For this reason, a source gas is excited into plasma in a relatively large region within the conventional nozzle 300′, allowing source gases react to one another and deposit material on an inner sidewall of the nozzle 300′. On the other hand, the plasma formation region is reduced in the inventive nozzle 300, thus preventing or reducing the deposition of material on the inner surfaces of the example invention nozzle 300.

In the case where the source gas supplied from a nozzle contains silane gas (SiH₄), helium gas (He), and oxygen gas (O₂), the silicon content of the silicon oxides deposited on the inner sidewall surfaces of a nozzle will tend to be relatively high in comparison with the silicon oxide films being formed essentially simultaneously on a substrate positioned in the process chamber. In a test for evaluating the distribution of radical species within the process chamber, it was found that oxygen radicals and helium radicals tended to be rather uniformly distributed relative to the silane radicals that tended to be heavily concentrated around the nozzle.

Without being bound by any particular theory, it is suspected that this result occurs because the silane gas is more reactive and tends to be resolved more readily than other gases included in a typical source gas mixture. By reducing the formation or deposition of silicon oxides and/or other reaction products or byproducts on the peripheral surfaces of the nozzle, the invention improves performance and/or may reduce the overetch of the other surfaces within the process chamber during periodic cleaning, particularly for processes that utilize silane gas, for example, oxide depositions.

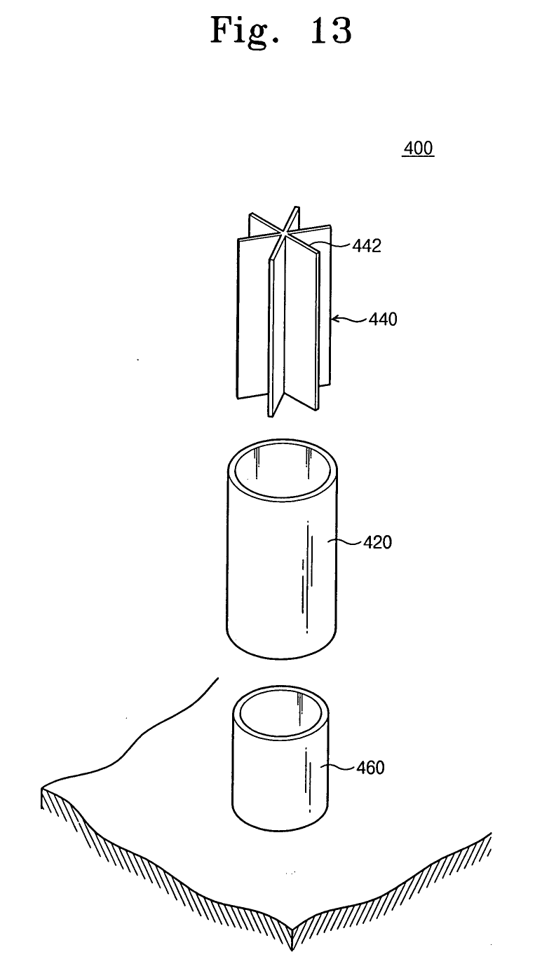

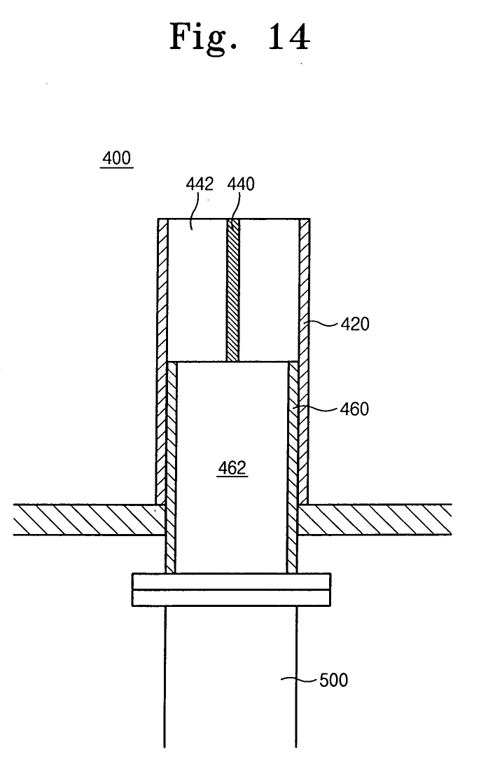

Further, with regard to the embodiment of the invention illustrated in FIGS. 13 and 14, the various component parts, 460, 420 and/or 440 could be provided with one or more mechanical fastening structures, e.g., a pin and follower arrangement that would provide a positive “lock” feature sufficient to maintain the spatial relationship between two or more components. This functionality would reduce the maintenance time associated with the plasma apparatus and provide for rapid changes to adjust for changes in the product loading and/or process adjustments. Similarly, the improved functionality would reduce the time associated with changing the nozzles.

Similarly, improving the ease with which the apparatus could be adapted for particular uses and maintenance by allowing workers to quickly shift between various configurations of the multiple channel regions to adapt the device for a particular process or processes. Similarly, the ability to modify or repair the apparatus may allow service personnel to repair the apparatus more easily.

If the paths 341 provided through the multiple channel section 340 are too short, source gases in the multiple channel section 320 may be excited by the high-frequency energy. Therefore, the multiple channel section 340 (or the insertion member 344) should be long enough to suppress (where “suppress” may mean eliminate or reduce) excitation of the source gases into plasma within the multiple channel portion. Multiple channel sections 340 having a length of at least 4 millimeters, or even better, at least 10 millimeters, will generally be sufficient to suppress (where “suppress” may mean eliminate or reduce) plasma formation.

A nozzle 400 illustrated in FIGS. 13 and 14 is a modified version of the nozzle 300 illustrated in FIG. 3. FIG. 13 is an exploded perspective view of the nozzle 400, and FIG. 14 is a cross-sectional view of a coupled nozzle 400. The nozzle 400 includes a supply pipe 460, an outer pipe 420, and an insertion member 440. The supply pipe 460 is connected to an external gas supply assembly 500 and is installed so as to protrude into the process chamber.

Particularly with respect to the embodiment of the invention illustrated in FIGS. 13 and 14, we would suggest that the various component parts, 460, 420 and 440 could be provided with one or more fastening structures, e.g., a pin and follower arrangement, that could simplify maintenance by allowing workers to quickly shift between the multiple channel regions having different configurations to allow the functional portions of the nozzles to be customized for certain etch and deposition processes and/or repaired or reworked depending on the nature of the problem.

The outer pipe 420 has an inside diameter that corresponds to an outside diameter of the supply pipe 460. The outer pipe 420 is longer than the supply pipe, and will increase the path length when applied over the supply pipe 460. The insertion member 440 is inserted into the outer pipe 420 and may have the same configuration as the insertion member 440 shown in FIG. 3 or FIG. 8 (not shown). The number of plates 442 provided to the insertion member 440 may be variable.

The plates 442 have a sufficient width so that the insertion member 440 will be supported by the supply pipe 460 when inserted into the outer pipe 420. Due to the above-described configuration, the supply pipe 460 serving as a single channel section of the nozzle 400 with the protruding portion of the outer pipe 420 serving as a multiple channel section. A length of the insertion member 440 may be substantially equal to that of the upwardly protruding outer pipe 420. The insertion member 440 has a length of at least 4 millimeters, preferably, at least 10 millimeters. Since the supply pipe 460 supports the insertion member 440, the insertion member 440 may be installed readily.

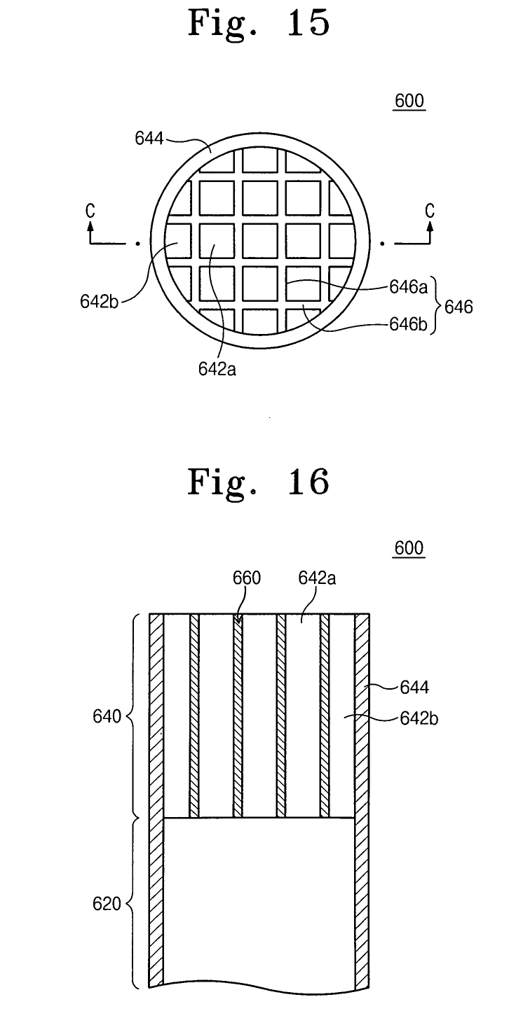

A nozzle 600 illustrated in FIG. 15 and FIG. 16 is still another modified version of the nozzle 300 illustrated in FIG. 3. FIG. 15 is a top plan view of the nozzle 600, and FIG. 16 is a cross-sectional view taken along a line C-C of FIG. 15. Substantially, the nozzle 600 has the same configuration as the nozzle 300 illustrated in FIG. 3, except a shape of an insertion member 646. Now, the insertion member 646 will be described more fully below.

The insertion member 646 includes a plurality of first members 646a arranged in one direction and a plurality of second members 646b arranged so as to cross the first member 646a and thereby divide the opening into a series of paths 642. The direction of the first members 646a may be perpendicular to that of the second members 646b to form a “lattice” type configuration as illustrated in FIG. 15 with some more centrally located rectangular paths 642a surrounded by some truncated or partial paths 642b.

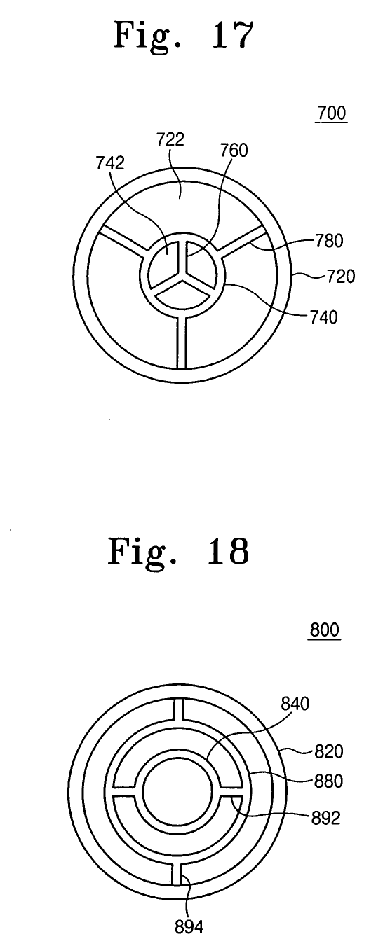

Other modified versions of the nozzle 300 shown in FIG. 3 are illustrated in FIG. 17 through FIG. 19, respectively. The nozzles illustrated in FIGS. 17-19 share the same basic configuration as the nozzle 300 illustrated in FIG. 3, with the exception of the specific shapes or profiles of multiple channel sections. Referring to FIG. 17, a multiple channel section of a nozzle 700 includes an outer pipe 720, an inner pipe 740, and an insertion member 760. The outer pipe 720 extends from a single channel section. The inner pipe 740 is inserted into the outer pipe 720.

The multiple channel section has a circular path 742 disposed at the center of the inner pipe 740 and a ring-shaped path 722 disposed to surround the circular paths 742. In the outer pipe 740, an insertion member 760 having the same configuration as illustrated in FIG. 3 or FIG. 8 may be provided for dividing the path in the inner pipe 740 into a plurality of paths. The number of plates forming the insertion member 760 may be variable.

Further, a plurality of plates 780 may be provided for dividing the annular path 722 disposed between the inner and outer pipes 740 and 720 into a plurality of paths. Each of the plates 780 may be flat and rectangular, having one edge in contact with the inner pipe 740 and an opposing edge in contact with the outer pipe 720. Although they have been described as separate components that are assembled to form the final structure, the inner pipe 740 and the insertion member 760 may be manufactured as a single unit. Similarly, the outer pipe 720, the inner pipe 740 and the insertion member 760 may be manufactured as a single unit or as a collection of components or subassemblies that are subsequently combined to form the final structure.

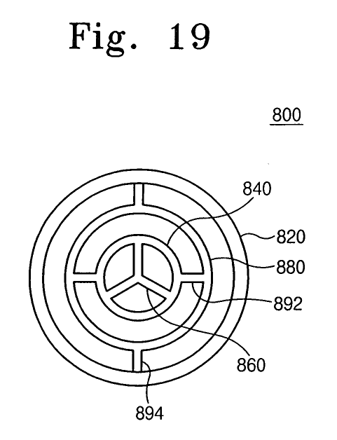

As illustrated in FIG. 18, a multiple channel section of a nozzle 800 may include an inner pipe 820, an outer pipe 840, an insertion member 880, and plates 892 and 894. The outer pipe 840 extends from a single channel section with the inner pipe 820 being inserted into the outer pipe 840. An insertion pipe 880 is positioned between the outer pipe 840 and the inner pipe 820. Plates 892 and 894 may also be provided between the inner pipe 820 and the insertion pipe 880 and between the insertion pipe 880 and the outer pipe 840, respectively. Alternatively, the insertion member 860 may be installed in an inner pipe of FIG. 18 for dividing the path through the inner pipe into a plurality of paths, as illustrated in FIG. 19.

Other modifications and variations to the invention will be apparent to a person skilled in the art from the foregoing disclosure. Thus, while only certain embodiment of the invention has been specifically described herein, it will be apparent that numerous modifications may be made thereto without departing from the spirit and scope of the invention.

What is claimed is:

1. A nozzle for introducing a source gas into a substrate processing chamber comprising:
a single channel section for receiving the source gas; and
a multiple channel section for receiving the source gas from the single channel section and directing the source gas into the substrate processing chamber;
wherein a plurality of gas flow paths are provided through the multiple channel section, and
further wherein each of the plurality of gas flow paths has a cross sectional area that is smaller than a cross section of the single channel section.

2. The nozzle of claim 1, wherein:
the single channel and multiple channel sections of the nozzle are substantially collinear; and
each of the plurality of gas flow paths has a maximum opening dimension generally perpendicular to a gas flow direction sufficient to suppress formation of a plasma within the gas flow paths.

3. The nozzle of claim 2, wherein:
the multiple channel section includes
a generally cylindrical inner wall defining an inner volume; and
an insertion member including at least one open cylindrical element arranged in a generally collinear orientation with the inner volume thereby defining at least one annular gas flow path.

4. The nozzle of claim 3, wherein:
the insertion member further includes at least one plate arranged so as to cross an annular gas flow path and form an arcuate gas flow path.

5. The nozzle of claim 2, wherein:
the multiple channel section includes
a generally cylindrical inner wall defining an inner volume; and
a plurality of plates arranged in a generally radial configuration within the inner volume, the plates extending from near a central axis of the multiple channel section toward the inner wall, thereby separating the inner area into the plurality of gas flow paths.

6. The nozzle of claim 5, wherein:
the plurality of radially arranged plates are assembled to form an insertion member, the insertion member then being positioned within the multiple channel section, thereby separating the inner area into the plurality of gas flow paths.

7. The nozzle of claim 5, wherein:
the number of the plates is from 3 to 8;
the plates are arranged at even angular intervals; and
a portion of the plates within the multiple channel section extends in an upstream direction at least 4 mm from an outlet opening in the multiple channel section.

8. The nozzle of claim 1, wherein:
the multiple channel section includes
an inner wall defining an inner area;
a central wall defining a first gas path through the multiple channel section; and
a plurality of plates arranged in the annular area formed between the central wall and the inner wall, thereby separating the annular area into multiple gas flow paths.

9. The nozzle of claim 1, wherein:
the multiple channel section includes
an inner wall defining an inner area;
a central wall defining a first gas path through the multiple channel section;
an intermediate wall arranged between the inner wall and the central wall and defining a first channel area between the intermediate wall and the central wall and a second channel area between the intermediate wall and the inner wall;
a first plurality of plates arranged in the first channel area for separating the first channel area into multiple gas flow paths; and
a second plurality of plates arranged in the second channel area for separating the second channel area into multiple gas flow paths.

10. A nozzle configured for introducing source gases into a substrate processing chamber, comprising:
a supply pipe, an outer pipe and an insertion member
wherein the supply pipe extends into the substrate processing chamber and as is configured for receiving the source gases from an external gas supply assembly and delivering the source gas to the outer pipe;
wherein the outer pipe has a lower portion configured to surround and engage a downstream portion of the supply pipe and an upper portion configured for receiving the insertion member; and
wherein the insertion member disposed in the upper portion of the outer pipe forms a plurality of gas flow paths thorough the upper portion of the outer pipe.

11. The nozzle of the claim 10, wherein:
the insertion member includes a plurality of plates.

12. The nozzle of claim 11, wherein:
the number of the plates is from 3 to 8;
the plates are radially arranged at even angular intervals; and
a portion of the plates within the multiple channel section extends in an upstream direction at least 4 mm from a gas outlet opening into the substrate processing chamber.

13. The nozzle of claim 10, wherein:
the plurality of gas paths includes a central gas path and a plurality of peripheral gas paths arranged around the central gas path.

14. The nozzle of claim 10, wherein:
the plurality of gas paths includes
a central gas path;
a first annular gas path; and
a second annular gas path, wherein the central gas path, the first annular gas path and the second annular gas path are arranged in a generally coaxial configuration.

15. The nozzle of claim 14, wherein:
at least one of the first annular gas path and the second annular gas path is divided into a plurality of arcuate gas paths.

16. The nozzle of claim 10, wherein:
the insertion member includes a first plurality of plates oriented in a first direction and at least one other plate oriented in a direction generally perpendicular to the first direction to form a lattice structure.

17. An apparatus for introducing a source gas into a plasma chamber through a nozzle comprising:
a process chamber;
a substrate supporter configured for receiving and holding a substrate within the process chamber;
a nozzle configured for injecting a source gas into the process chamber; and
an energy source for applying sufficient energy to the source gas within the process chamber to form a plasma;
wherein an inlet section of the nozzle includes a single gas channel and an outlet section of the nozzle includes a plurality of gas channels through which the source gas passes as it enters the process chamber;
and further wherein the plurality of gas channel outlet sections have an area and a length sufficient to suppress formation of a plasma within the nozzle.

18. The apparatus of claim 17, wherein:
the length of the plurality of gas channels outlet sections is at least 4 mm:

19. The apparatus of claim 17, the multiple channel section further comprising:
an outer pipe extending from the single channel section; and
an insertion member inserted into the outer pipe to divide the inside of the outer pipe into a plurality of gas channels;
wherein the insertion member includes a plurality of plates having a first edge disposed toward the center of the outer pipe and an opposing edge that is in contact with or closely adjacent an inner sidewall of the outer pipe.

20. The apparatus of claim 19, wherein:
the insertion member provides a central gas path surrounded by one or more peripheral gas paths through at least an outlet portion of the multiple channel section.

21. The apparatus of claim 17, wherein:
the plasma formed within a process chamber produces a deposition material which deposits on exposed surfaces of the substrate and the process chamber.

22. The apparatus of claim 17, wherein:
a second plasma formed within the process chamber tends to etch the deposition material from exposed surfaces.

23. A method of fabricating a nozzle assembly comprising:
preparing a supply pipe having an outer portion defining an outer surface;
preparing an outer pipe having an inner region defining a first inner surface corresponding to the outer surface of the supply pipe and an outer region defining a second inner surface bounding an outer passage;
guiding the outer pipe onto the supply pipe whereby the first inner surface and the outer surface mate and thereby fix the outer pipe on the supply pipe to form an extended gas conduit; and
placing an insertion member into the outer passage, the insertion member being configured to engage the second inner surface and divide the outer passage into multiple gas channels.

24. The method according to claim 23, wherein placing an insertion member into the outer passage further comprises:
advancing the insertion member through the outer region of the outer pipe until the insertion member contacts an upper surface of the supply pipe.

25. The nozzle of claim 5, wherein:
the plurality of radially arranged plates are assembled to form an insertion member, the insertion member then being positioned within the multiple channel section, thereby separating the inner area into the plurality of gas flow paths.

26. An apparatus for introducing a source gas into a plasma chamber through a nozzle assembly comprising:
a plasma chamber defined by a chamber wall;
a supply pipe extending into the plasma chamber from the chamber wall;
an outer pipe that surrounds and is attached to a distal portion of the supply pipe, the outer pipe and the supply pipe cooperating to define a single gas channel; and
an insertion member positioned within the outer pipe to divide the single gas channel into a plurality of gas channels from which the source gas will enter the plasma chamber through which the source gas passes as it enters the process chamber.
